(19) United States
(12) Patent Application Publication
(10) Pub. No.: US 2025/0250464 A1
(43) Pub. Date: Aug. 7, 2025

(54) JANUS ABRASIVE PARTICLES AND SLURRY COMPOSITION COMPRISING THE SAME FOR CHEMICAL MECHANICAL POLISHING

(71) Applicant: Samsung Electronics Co., Ltd., Suwon-si (KR)

(72) Inventors: Nahyun An, Suwon-si (KR); Donghoon Kwon, Suwon-si (KR)

(21) Appl. No.: 18/944,160

(22) Filed: Nov. 12, 2024

(30) Foreign Application Priority Data
Feb. 2, 2024 (KR) 10-2024-0016941

(51) Int. Cl. C09G 1/02; B24B 37/04; C09K 3/14; H01L 21/3105; H01L 21/321

(52) U.S. Cl. CPC C09G 1/02; B24B 37/044; C09K 3/1436; H01L 21/31053; H01L 21/3212

(57) ABSTRACT

A slurry composition used for chemical mechanical polishing includes a plurality of Janus abrasive particles; and a solvent in which the plurality of Janus abrasive particles are dispersed, wherein each of the plurality of Janus abrasive particles includes: a core particle; a first coating portion on a surface of the core particle; and a second coating portion on the surface of the core particle, wherein the each of the plurality of Janus abrasive particles has a hydrophobic area and a hydrophilic area defined by the first and second coating portions.

### CROSS-REFERENCE TO RELATED APPLICATIONS

This application claims priority under 35 U.S.C. § 119 to Korean Patent Application No. 10-2024-0016941 filed on Feb. 2, 2024, in the Korean Intellectual Property Office, the disclosure of which is incorporated by reference herein in its entirety.

### BACKGROUND

Embodiments of the present disclosure described herein relate to Janus abrasive particles used in chemical mechanical polishing and a slurry composition comprising the same.

Recently, as semiconductor devices have become more diverse and highly integrated, finer pattern formation techniques are being used. In addition, with the development of fine pattern formation technology, the surface structure of semiconductor devices has become more complex, and interlayer flatness in each process is a very important factor in improving the precision of photolithography. In manufacturing semiconductor devices, a CMP (chemical mechanical polishing) process is used as a planarization technology. For example, the CMP is also widely used in a process for removing an excessively deposited insulating film for interlayer insulation, a process for planarizing an interlayer dielectric film and an insulating film for STI (shallow trench isolation) which insulates chips from each other, and in a process for forming metal conductive films such as contact plugs, via contacts, etc.

### SUMMARY

In some embodiments, a slurry composition with high polishing efficiency may be provided while also reducing or minimizing defects such as scratches in the chemical mechanical polishing process. Additionally, abrasive particles used in the slurry composition may be provided.

In some aspects of the present disclosure, a slurry composition includes a plurality of Janus abrasive particles; and a solvent in which the plurality of Janus abrasive particles are dispersed, wherein each of the plurality of Janus abrasive particles includes: a core particle; a first coating portion on a surface of the core particle; and a second coating portion on the surface of the core particle, wherein the each of the plurality of Janus abrasive particles have a hydrophobic area and a hydrophilic area defined by the first and second coating portions.

In some embodiments of the present disclosure, the core particle may be selected from the group consisting of silica, zirconia, titania, ceria, and surface-modified inorganic oxide particles, and combinations thereof.

In some embodiments of the present disclosure, the core particle may be made of silica, and the second coating portion may be made of ceria.

In some embodiments of the present disclosure, the core particle may include a core and a shell surrounding or on the core.

In some embodiments of the present disclosure, the core may include a metal oxide and the shell includes an inorganic oxide.

In some embodiments of the present disclosure, the first coating portion may include a hydrophobic polymer.

In some embodiments of the present disclosure, the hydrophobic polymer may include at least one of acrylic, epoxy, polyethylene, polystyrene, polyvinyl chloride, polytetrafluoroethylene, polydimethylsiloxane, polyester, and polyurethane.

In some embodiments of the present disclosure, at least a portion of the second coating portion may be on the first coating portion.

In some embodiments of the present disclosure, the first coating portion may include a surface-modified inorganic oxide.

In some embodiments of the present disclosure, the surface-modified inorganic oxide is provided as a composite including one of a cationic polymer, an anionic polymer, or a nonionic polymer.

In some embodiments of the present disclosure, the slurry composition for the chemical mechanical polishing may further include a film portion on the second coating portion.

In some embodiments of the present disclosure, the film portion may include an ionic polymer having charges of an opposite polarity to a polarity of a target to be polished.

In some embodiments of the present disclosure, the second coating portion may cover 50% inclusive to 100% exclusive of a surface of the core particle.

In some aspects of the present disclosure, a particle for chemical mechanical polishing having a hydrophobic surface area and a hydrophilic surface area includes a core particle; a first coating portion on a surface of the core particle; and a second coating portion on the surface of the core particle, wherein a hydrophobic area and a hydrophilic area are defined by the first and second coating portions.

In some aspects of the present disclosure, a method for manufacturing Janus abrasive particles contained in a slurry composition for chemical mechanical polishing includes forming a hydrophobic first coating portion on at least a partial area of a surface of the core particle; placing the core particle on a substrate so that at least a portion of the core particles contacts the substrate; and forming a hydrophilic second coating portion on the core particle while the core particle is in contact with the substrate.

In some embodiments of the present disclosure, the first hydrophobic coating portion may be formed by coating a hydrophobic material on the surface of the core particle before placing the core particle on the substrate.

In some embodiments of the present disclosure, the hydrophobic first coating portion may be formed using chemical vapor deposition, physical vapor deposition, or solution phase reaction.

In some embodiments of the present disclosure, the core particle may be magnetic, and an electrode or a magnet may be placed on an opposite surface to one surface of the substrate on which the core particle is positioned such that the substrate is between the electrode or the magnet and the core particle, and thus the core particle is attached to the substrate under a magnetic force.

In some embodiments of the present disclosure, the substrate may have softness, and a formation area size of the hydrophilic second coating portion may be controlled based on a contact area size between the core particle and the substrate.

In some aspects of the present disclosure, a chemical mechanical polishing method includes transferring the slurry composition as described above onto a surface of an abrasive pad of a chemical mechanical polishing apparatus; placing a surface of a polishing target such that the slurry composition is between the target and the abrasive pad; and contacting the surface of the target with the slurry composition to polish the surface of the polishing target with the slurry composition.

According to some embodiments of the present disclosure, the Janus abrasive particles may be in the slurry composition for chemical mechanical polishing, the scratch defects may be reduced, and the polishing etch percentage may be increased, such that polishing efficiency on the target to be polished may be improved.

### BRIEF DESCRIPTION OF THE FIGURES

The above and other objects and features of the present disclosure will become apparent by describing in detail embodiments thereof with reference to the accompanying drawings.

FIG. 1A and FIG. 1B are cross-sectional views showing Janus abrasive particles according to some embodiments of the present disclosure, respectively.

FIG. 2 is a cross-sectional view showing Janus abrasive particles according to some embodiments of the present disclosure.

FIG. 3A to FIG. 3C are cross-sectional views showing an abrasive particle according to some embodiments of the present disclosure, respectively.

FIG. 4 is a cross-sectional view showing an abrasive particle according to some embodiments of the present disclosure.

FIG. 5 is a conceptual diagram showing abrasive particles being anisotropically oriented in a slurry composition for chemical mechanical polishing according to some embodiments of the present disclosure.

FIG. 6A is a flowchart sequentially showing a method for manufacturing Janus abrasive particles according to some embodiments of the present disclosure, and FIG. 6B is a cross-sectional view which sequentially shows a method for forming the Janus abrasive particles according to some embodiments of the present disclosure.

FIG. 7A is a flowchart sequentially showing a method for manufacturing another type of the Janus abrasive particles according to some embodiments of the present disclosure, and FIG. 7B a cross-sectional view which sequentially shows a method for forming the Janus abrasive particles according to some embodiments of the present disclosure.

FIGS. 8A to 8C illustrate processes of forming a second coating portion by varying a contact area size between core particles and a substrate, respectively.

### DETAILED DESCRIPTION

Hereinafter, embodiments of the present disclosure will be described clearly and in detail so that a person skilled in the art of the present disclosure may easily perform the present disclosure.

In semiconductor manufacturing, chemical mechanical polishing (CMP) is a process in planarization technology. In the chemical mechanical polishing process, mechanical processing using abrasive particles between a target to be polished and an abrasive pad of a chemical mechanical polishing apparatus and chemical etching by a slurry composition occur simultaneously. In other words, the chemical mechanical polishing is a process that chemically changes a surface of the target to be polished with an acidic or basic solution to instantly form a weakly bonded layer in the surface, and then mechanically removes the formed layer using the abrasive particles. In this regard, the surface of the target to be polished is mechanically polished using the abrasive particles by applying a pressure to the target while supplying the abrasive particles to the surface of the target to be polished.

The present disclosure relates to a slurry composition used in chemical mechanical polishing. The present disclosure relates specifically to the slurry composition used during chemical mechanical polishing of various films used in the semiconductor manufacturing process. The slurry composition used in the semiconductor manufacturing process may include a slurry composition for an insulating film or a slurry composition for a metal film. In some embodiments of the present disclosure, the slurry composition for the insulating film may be used to polish oxide films such as silicon oxide films during the semiconductor manufacturing process, polish a surface of a silicon substrate after constituting a trench, or polish interlayer insulating films such as gate insulating films. The slurry composition for the metal films may be used to polish wiring, electrodes, vias/contacts, barrier metals, etc. within the semiconductor manufacturing process. Alternatively, the slurry composition may be used to polish a film other than an insulating film or a metal film, such as a polysilicon film.

The slurry composition for chemical mechanical polishing according to some embodiments of the present disclosure may include Janus abrasive particles having different chemical and/or physical properties in a surface thereof, and a solvent in which the Janus abrasive particles are dissolved and/or dispersed.

In some embodiments of the present disclosure, the Janus abrasive particles may be contained at 0.01 wt % to 20 wt % based on a total weight of the abrasive slurry composition. For example, the Janus abrasive particles may be contained at 0.01 wt % to 10 wt %, 0.01 wt % to 5 wt %, 0.01 wt % to 3 wt %, 0.01 wt % to 1 wt %, 0.01 wt % to 0.5 wt %, 0.01 wt % to 0.3 wt %, or 0.01wt % to 0.1 wt % relative to the total weight of the slurry composition.

When the content of the Janus abrasive particles is larger than the above range, the possibility of agglomeration of the Janus abrasive particles within the slurry composition increases. When there is a lot of agglomeration of the Janus abrasive particles, there is a possibility of defects such as scratches on the target to be polished. In addition, there is a high possibility that the abrasive particles may remain on the surface of the target to be polished until after the polishing and thus may act as foreign substances. When the content of the Janus abrasive particles is smaller than the above range, a polishing speed on the target to be polished may be too low, resulting in reduced polishing efficiency.

The solvent may be any solvent used in the slurry composition for chemical mechanical polishing. For example, the solvent may be deionized water. However, the present disclosure is not limited thereto. In some embodiments of the present disclosure, the solvent may be ultrapure water.

In some embodiments of the present disclosure, the solvent may include water (e.g., deionized water) as an aqueous carrier and may include one or more water-miscible organic solvents. Examples of the organic solvents that may be used may include alcohols such as propenyl alcohol, isopropyl alcohol, ethanol, 1-propanol, methanol, 1-hexanol, etc.; aldehydes such as acetylaldehyde and the like; ketones such as acetone, diacetone alcohol, methyl ethyl ketone, etc.; esters such as ethyl formate, propyl formate, ethyl acetate, methyl acetate, methyl lactate, butyl lactate, ethyl lactate, etc.; ethers including sulfoxides such as dimethyl sulfoxide (DMSO), tetrahydrofuran, dioxane, diglyme, etc.; amides such as N,N-dimethylformamide, dimethylimidazolidinone, N-methylpyrrolidone, etc.; polyhydric alcohols and their derivatives such as ethylene glycol, glycerol, diethylene glycol, diethylene glycol monomethyl ether, etc.; and nitrogen-containing organic compounds such as acetonitrile, amylamine, isopropylamine, dimethylamine, etc.

In some embodiments of the present disclosure, a content of the solvent may be a remaining content excluding the abrasive particles with respect to a total content of the slurry composition for chemical mechanical polishing. When the slurry composition for chemical mechanical polishing may include additional additives, the content of the solvent may be a remaining content excluding a content of the abrasive particles and the additives.

The Janus abrasive particles function as particles used in chemical mechanical polishing, and their surfaces have two or more different physical/chemical properties. Because the Janus abrasive particles have surfaces with the different physical/chemical properties in different areas, different types of chemical reactions may occur in the different areas. For example, the Janus abrasive particles according to some embodiments of the present disclosure may include a hydrophobic area and a hydrophilic area. The hydrophilic and hydrophobic areas allow the abrasive particles to be oriented in a specific direction, that is, anisotropically, when polishing the target to be polished using an abrasive slurry composition. For example, when the abrasive slurry composition is on a hydrophilic or hydrophobic device surface, the abrasive particles are attracted to the device surface in an area that has the same properties as those of the device surface. Due to this attraction, the particles are adsorbed in a specific direction such that their orientations may be controlled.

In addition, because the surface has regions that are hydrophilic and regions that are hydrophobic, the agglomeration phenomenon where the abrasive particles agglomerate is significantly reduced. This is because the hydrophilic and hydrophobic areas have different surface energies, which may cause repulsion between adjacent particles, and various reactive groups located on the surface or interface of the hydrophilic particles dissociate depending on pH, causing the surface of the particle to become partially negatively charged, such that the particle has electrochemical stability.

This is described with referring to the drawings as follows.

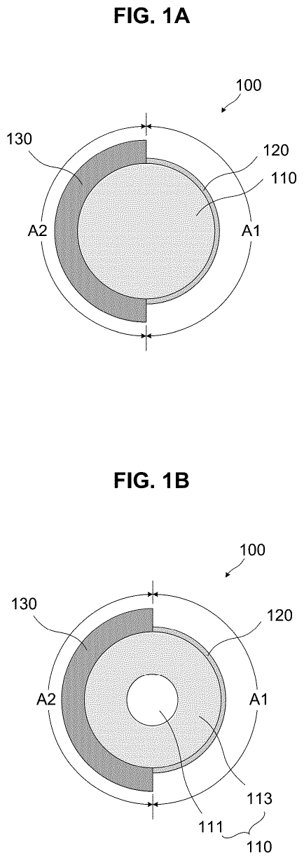

FIG. 1A and FIG. 1B show Janus abrasive particles 100 according to some embodiments of the present disclosure.

Referring to FIG. 1A and FIG. 1B, the Janus abrasive particle 100 according to some embodiments of the present disclosure may include a core particle 110, a first coating portion 120 on one portion of the core particle 110, and a second coating portion 130 on the other portion of the core particle 110.

The core particle 110 may constitute a main body of the Janus abrasive particle 100 and may be generally provided in a spherical shape.

The core particle 110 may include an inorganic oxide particle, for example, made of silica, zirconia, titania, ceria, or a combination thereof. Additionally, the core particle 110 may include a surface-modified inorganic oxide particle. However, the material of the core particle 110 is not limited thereto, and may include metal oxide particles, for example, made of a metal oxide of Fe, Al, La, Mn, Zn, Ca, Mg, Sr, Co, Ru, Os, Rh, Ir, It Ni, Pd, Pt, Cu, Ag, or Au.

In some embodiments of the present disclosure, the core particle 110 may include a magnetic material. Alternatively, when the core particle includes a non-magnetic material as its main component, the core particle may further may include a magnetic material. For example, the core particle 110 may further include a magnetic material in addition to the non-magnetic material, and the magnetic material may include, for example, Fe₃O₄, Fe₂O₃, Co₂Fe₃O₄, etc. Since the core particles 110 are magnetic, the Janus abrasive particles 100 may be easily manufactured using magnetic force. In addition, when the core particle 110 is magnetic, easy control using the magnetic force after manufacturing the Janus abrasive particles 100, for example, control of the orientation thereof in a specific direction may be possible.

The core particle 110 may be integrally formed and composed of only a single component. However, the present disclosure is not limited thereto and the core particle may include multiple components. For example, the core particle 110 may be provided in a form of a core 111 and a shell 113 on or surrounding the core 111.

When the core particle 110 has the form of the core 111 and the shell 113, the core 111 may include a metal or a metal oxide, and the shell 113 may include a metal oxide and/or an inorganic oxide. The metal or the metal in the metal oxide that constitutes the core 111 may be Fe, Zr, Al, La, Mn, Zn, Ca, Mg, Sr, Co, Ce, Ru, Os, Rh, Ir, Ni, Pd, Pt, Cu, Ag, Au, etc. A variety of metal oxides and/or inorganic oxides constituting the shell 113 may be used, and for example, may be SiO₂, CeO₂, Al₂O₃, ZrO₂, Fe₂O₃, Fe₃O₄, and La₂O₃.

In some embodiments of the present disclosure, at least one of the core 111 and the shell 113 may be made of a magnetic material. For example, the core 111 may be made of Fe₃O₄, Fe₂O₃, Co₂Fe₃O₄, etc. When the core 111 is magnetic, the shell 113 may or may not be magnetic. When the core 111 is not magnetic, the shell 113 may be made of a magnetic material. Thus, the core particle 110 may be magnetic.

Since the core particle 110 is magnetic, the core particle may be easily manufactured using a magnetic force when manufacturing the Janus abrasive particles 100. Even after manufacturing the Janus abrasive particles 100, the Janus abrasive particles 100 may be easily controlled using the magnetic force, for example, control of the orientation of the Janus abrasive particles 100 in a specific direction may be possible.

The surface of the core particle 110 may be coated such that different area thereof may be coated with different materials to have different chemical/physical properties, for example, hydrophilic and hydrophobic properties.

In some embodiments of the present disclosure, the surface of the Janus abrasive particles 100 may have two different areas with different chemical/physical properties. The two areas may be a hydrophobic area A1 which is hydrophobic, and a hydrophilic area A2 which is hydrophilic. The hydrophobic area A1 is an area where a hydrophobic material is on the core particle 110, and the hydrophilic area A2 is an area where a hydrophilic material is on the core particle 110. In some embodiments of the present disclosure, the hydrophilic area A2 and the hydrophobic area A1 do not overlap each other. For example, on the surface of the core particle 110, an area corresponding to one hemisphere may be the hydrophobic area A1, and an area corresponding to the other hemisphere may be the hydrophilic area A2.

When each of different portions coated with different materials is referred to as a coating portion, the coating portions may include the first coating portion 120 and the second coating portion 130. The first coating portion 120 may be provided in the hydrophobic area A1, and the second coating portion 130 may be provided in the hydrophilic area A2.

One of the first coating portion 120 and the second coating portion 130 may be used to control a behavior of the Janus abrasive particles 100 by orienting the particles in a specific direction, and the other thereof may be used for efficiently polishing the polishing target. In the present disclosure, one example in which the first coating portion 120 among the first coating portion 120 and the second coating portion 130 controls the behavior of the Janus abrasive particles 100 by orienting the particles in a specific direction while the second coating portion 130 is used to efficiently polish the target to be polished will be described.

The first coating portion 120 and the second coating portion 130 may include different materials having different chemical/physical properties, such as hydrophobic and hydrophilic properties, as described above. For example, the first coating portion 120 may include a hydrophobic polymer. In some embodiments of the present disclosure, the hydrophobic polymer may include acrylic, epoxy, polyethylene, polystyrene, polyvinyl chloride, polytetrafluoroethylene, polydimethylsiloxane, polyester, polyurethane, etc. However, the hydrophobic polymer is not limited thereto, and various hydrophobic polymers may be used.

In some embodiments of the present disclosure, the first coating portion 120 may include an ionic polymer having a specific charge. For example, the first coating portion 120 may include a cationic polymer or an anionic polymer.

The second coating portion 130 may include various types of materials, such as metal oxide, surface-modified metal oxide, inorganic oxide, or inorganic oxide, so that the target to be polished may be easily polished thereby. For example, the second coating portion 130 may be made of SiO₂, CeO₂, Al₂O₃, ZrO₂, Fe₂O₃, Fe₃O₄, La₂O₃, or a combination thereof. The material used for the second coating portion 130 may be different from that of the core particle 110. For example, silica may be used as the material of the core particle 110 and ceria may be used as the material of the second coating portion 130. When ceria is used as the material of the second coating portion 130, the removal selectivity relative to a specific material of the abrasive target may be increased. When ceria is coated on the abrasive particles, the ceria particles may exist in an ionized form, for example, Ce³⁺, within the slurry composition. The ceria abrasive particles exhibit a higher polishing rate on a silicon oxide insulating film compared to a silicon nitride insulating film. This is the result of forming a large amount of Ce—O—Si bonds by increasing a reaction rate of Ce³⁺ with Si—O—, which may increase the polishing rate on the silicon oxide insulating film. The surface-modified inorganic oxide may be surface-modified with an organic material. In this case, the inorganic oxide may be the same inorganic oxide as that of the core particle 110 or a different inorganic oxide from that of the core particle 110. For example, silica may be used as the material of the core particle 110, and the surface-modified ceria or surface-modified silica may be used as the material of the second coating portion 130.

In one example of the present disclosure, the surface-modified inorganic oxide may be prepared via a coupling reaction on the surface of the inorganic oxide using a polymer graft. For example, it may be produced by coupling a hydroxyl group of an inorganic oxide with a prepolymer having a terminal group that reacts with the hydroxyl group. Examples of the terminal group that reacts with the hydroxyl group may include a reactive group such as isocyanate groups, trialkoxysilyl groups, and chlorosilyl groups. However, the method for producing the surface-modified inorganic oxide is not limited thereto, and the surface-modified inorganic oxide may be produced using various other methods, for example, radical polymerization reaction on the surface.

The material that may be used in the surface-modified inorganic oxide may include cationic monomers and/or polymers, anionic monomers and/or polymers, or nonionic monomers and/or polymers.

However, the material used for the second coating portion 130 is not limited thereto, and may be at least partially the same as a component constituting the core particle 110.

In some embodiments of the present disclosure, the first coating portion 120 and the second coating portion 130 may be provided on the core particle 110 so as to have substantially the same thickness. However, the present disclosure is not limited thereto, and the first coating portion 120 and the second coating portion 130 may be provided on the core particle 110 so as to have different thicknesses. For example, the first coating portion 120 may be smaller than the second coating portion 130. The thickness of each of the first coating portion 120 and the second coating portion 130 may vary depending on the polishing environment of the abrasive particles, for example, depending on the target to be polished.

In some embodiments of the present disclosure, the slurry composition may be provided in a colloidal type. In this case, the Janus abrasive particles 100 may be colloidal particles. When the Janus abrasive particles 100 are provided in the colloidal type, the Janus abrasive particles 100 may have a zeta potential value of 1 mV to 100 mV, 1 mV to 80 mV, 5 mV to 60 mV, or 10 mV to 50 mV in a range of about 2 to about 12 pH.

In some embodiments of the present disclosure, the size of the Janus abrasive particles 100 may vary depending on the target to be polished or the composition of the slurry composition. The Janus abrasive particles 100 may have a diameter of a nanometer scale, for example, in a range of several to hundreds of nm. For example, the size of the Janus abrasive particles 100 may be in a range of 1 nm to 200 nm, or 1 nm to 100 nm, or 1 nm to 50 nm. In another example, the size of the Janus abrasive particles 100 may be in a range of 1 nm to 30 nm, or 1 nm to 20 nm, or 1 nm to 10 nm, or 1 nm to 5 nm.

When the size of the Janus abrasive particles 100 is greater than the above range, the possibility of agglomeration thereof increases, and the possibility that the particles remain in an adsorbed state on the surface of the target to be polished increases. Conversely, when the size thereof is smaller than the above range, the polishing speed on the target to be polished may become too low, resulting in reduced polishing efficiency.

In some embodiments of the present disclosure, the slurry composition may further may include various additives in addition to the abrasive particles and the solvent.

In some embodiments of the present disclosure, the slurry composition may further may include a pH adjuster that allows the slurry composition to have a pH of about 2 to about 12.

The pH adjuster is used to adjust pH in consideration of a final pH of the composition, the polishing speed, polishing selectivity, etc., and may include one or more acid or base pH adjusters and buffering agents. As a pH adjuster, one that may adjust pH without affecting the properties of the slurry composition for chemical mechanical polishing may be used. In some embodiments of the present disclosure, the pH adjuster may be an acidic pH adjuster or a basic pH adjuster to achieve an appropriate pH.

In some embodiments of the present disclosure, examples of the pH adjusting agent may include at least one inorganic acid selected from the group consisting of sulfuric acid, hydrochloric acid, nitric acid, phosphoric acid, one or more organic acids selected from the group consisting of acetic acid, citric acid, glutaric acid, glucolic acid, formic acid, lactic acid, malic acid, malonic acid, maleic acid, oxalic acid, phthalic acid, succinic acid, and tartaric acid, one or more amino acids selected from the group consisting of lysine, glycine, alanine, arginine, valine, leucine, isoleucine, methionine, cysteine, proline, histidine, phenylalanine, serine, trisine, tyrosine, aspartic acid, tryptophan, and aminobutyric acid, imidazole, alkyl amines, alcohol amines, quaternary amine hydroxides, ammonia, or a combination thereof. In particular, the pH adjusting agent may be triethanolamine, tetramethylammonium hydroxide (TMAH or TMAOH), or tetraethylammonium hydroxide (TEAH or TEA-OH). Further, examples of the pH adjusting agent may include at least one selected from the group consisting of ammonium methyl propanol (AMP), tetra methyl ammonium hydroxide (TMAH), potassium hydroxide, sodium hydroxide, magnesium hydroxide, rubidium hydroxide, cesium hydroxide, sodium bicarbonate, sodium carbonate, triethanolamine, tromethamine, and niacinamide. In some embodiments of the present disclosure, the pH adjuster may be triethanolamine or aminobutyric acid.

The amount of pH adjuster may be provided in a range of about 0.0001 wt % to about 5 wt % based on the total weight of the slurry composition for chemical mechanical polishing. For example, the pH adjusting agent may be provided in an amount of from about 0.0005 wt % to about 1 wt %, or from 0.0005 wt % to about 0.5 wt %, or from about 0.001 wt % to about 0.1 wt %, relative to the total weight of the slurry composition for chemical mechanical polishing.

According to some embodiments of the present disclosure, the slurry composition may further include a surfactant. As the surfactant, for example, cationic surfactant, anionic surfactant, anionic polymer electrolyte, nonionic surfactant, amphoteric surfactant, fluorinated surfactant, mixtures thereof, etc. may be used.

The surfactant according to some embodiments of the present disclosure may be added to the slurry composition in an amount of 0.0001 wt % to 10 wt %, or 0.001% to about 2 wt %, or 0.001% to about 0.1 wt % based on the total slurry composition for chemical mechanical polishing.

The surfactant may be sufficient to achieve effective stabilization of the composition within the slurry composition for chemical mechanical polishing, and the content thereof may vary depending on the characteristics of the abrasive particle surface composed of a specific surfactant and metal oxide. For example, when the selected surfactant is not used sufficiently, it will have little or no effect on stabilizing the slurry composition for chemical mechanical polishing. Too much surfactant in the slurry composition for chemical mechanical polishing may cause unwanted foaming and/or flocculation in the composition.

The surfactant may include dodecyl sulfate sodium salt, sodium lauryl sulfate, dodecyl sulfate ammonium salt, alcohol ethoxylate, acetylenic surfactant, or a combination thereof.

The surfactant may be anionic, cationic, nonionic, or amphoteric surfactant. Additionally, two or more surfactants may be used in combination with each other.

The slurry composition for chemical mechanical polishing may include dispersion additives to stabilize the particle dispersion. The dispersion additives may include organic acids and their salts; polymeric acids and their salts; water-soluble copolymers and their salts; a copolymer containing at least two different types of acid groups, such as carboxylic acid groups, sulfonic acid groups, or phosphonic acid groups, within the same molecule of the copolymer, and salts thereof; polyvinylic acid and salts thereof, polyethylene oxide, polypropylene oxide, and combinations thereof. However, the present disclosure is not limited thereto. Examples of the polymer acids include, but are not limited to, polyacrylic acid, poly-methacrylic acid, polystyrene sulfonic acid, and salts thereof. The average molecular weight of the polymer may range from 1000 to 1,000,000, or from 2000 to 100,000, or from 10,000 to 50,000. The amount of the dispersion additive may be in a range of from about 0.0010 wt % to about 1.0 wt %, or from about 0.005% to about 0.5 wt %, or from about 0.01 wt % to about 0.25 wt %, based on the total weight of the slurry composition for barrier chemical mechanical polishing.

In some embodiments of the present disclosure, the slurry composition may further include an oxidizing agent and an oxidation catalyst depending on the target to be polished. For example, when the target to be polished is a metal, the slurry composition may further include an oxidizing agent, an oxidation catalyst, and/or a complexing agent.

The oxidizing agents may include one or more selected from the group consisting of hydrogen peroxide, urea, hydrogen peroxide, urea, percarbonate, periodic acid, periodate, perchloric acid, perchlorate, perbromic acid, perbromate, perboric acid, perborate, permanganic acid, permanganate, persulfate, bromate, chlorate, chlorite, chromate, iodate, iodic acid, ammonium peroxysulfate, benzoyl peroxide, calcium peroxide, barium peroxide, sodium peroxide and urea peroxide. However, the present disclosure is not limited thereto.

The oxidizing agent may be contained in an amount of 1 wt % to 10 wt %, 1 wt % to 8 wt %, or 3 wt % to 7 wt % based on the total weight of the slurry composition. When the oxidizing agent is higher than the above range, the flatness may deteriorate due to excessive oxidation of the metal film surface. When the oxidizing agent is smaller than the above range, the oxidation of the metal may be too small, leading to a problem of decreased polishing rate.

The oxidation catalyst may be a complex of one or more metals selected from the group consisting of Fe, Mn, Co, Ce, Ru, Os, Rh, Ir, Ni, Pd, Pt, Cu, Ag, and Au. According to one embodiment, the oxidation catalyst may be a complex of Fe. However, the present disclosure is not limited thereto. In some embodiments of the present disclosure, the complex may be an ammonium salt, potassium salt, or sodium salt having 1 to 4 carbonate, gluconate, sulfonate, or phosphate functional groups. According to one embodiment, the complex may be an ammonium salt, potassium salt, or sodium salt of Fe having two carbonates. However, the present disclosure is not limited thereto.

The oxidation catalyst may be contained in an amount of 0.01 wt % to 0.5 wt %, 0.01 wt % to 0.3 wt %, 0.01 wt % to 0.1 wt %, or 0.01 wt % to 0.05 wt %, based on the total weight of the slurry composition.

The complexing agent may be one or more selected from the group consisting of gluconic acid, citric acid, tartaric acid, lactic acid, oxalic acid, ascorbic acid, acetic acid, their sodium salts, their potassium salts, and their ammonium salts.

In some embodiments of the present disclosure, the abrasive particle may be deformed into various forms without departing from the concept of the present disclosure.

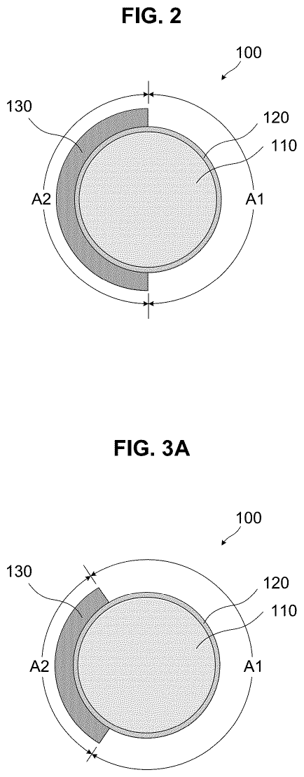

FIG. 2 is a cross-sectional view showing the Janus abrasive particles 100 according to some embodiments of the present disclosure which may be manufactured such that the hydrophilic area A2 and the hydrophobic area A1 are different from those in the above-described embodiment.

Referring to FIG. 2, in this embodiment, a hydrophobic material may be formed on a surface of the core particle 110. That is, the first coating portion 120 may be on and cover the surface of the core particle 110. In this regard, the second coating portion 130 may be on a portion of an outer surface of the first coating portion 120, and a portion of the outer surface of the first coating portion 120 that does not overlap the second coating portion 130 is exposed to the outside. Accordingly, the surface of the Janus abrasive particle 100 in the area where the second coating portion 130 is formed is hydrophilic, the area where the second coating portion 130 is formed becomes the hydrophilic area A2. The portion of the outer surface of the first coating portion 120 that does not overlap the second coating portion 130 and is exposed to the outside becomes the hydrophobic area A1.

In some embodiments of the present disclosure, the hydrophilic area A2 may be manufactured in a different manner from that in the above-described embodiment.

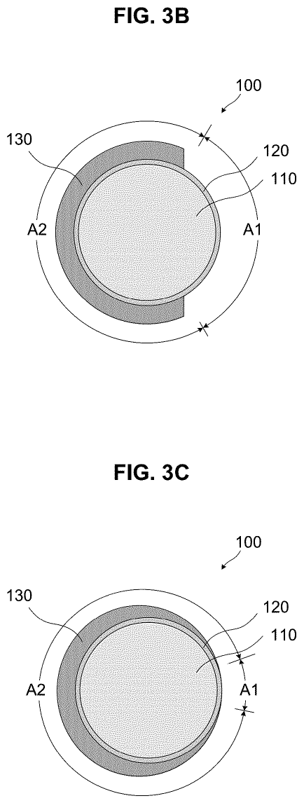

FIG. 3A to FIG. 3C are cross-sectional views showing an abrasive particle according to some embodiments of the present disclosure.

Referring to FIG. 3A to FIG. 3C, the area sizes of the hydrophobic area A1 exposed to the outside and the hydrophilic area A2 may be different from each other. For example, as shown in FIG. 3A, the area size of the exposed hydrophobic area A1 may be larger than the area size of the hydrophilic area A2. In this regard, the hydrophilic area A2 may be formed in a portion of the surface of the core particle 110, for example, in an area smaller than 50% of the surface thereof. Alternatively, as shown in FIG. 3B, the area size of the exposed hydrophobic area A1 may be smaller than the area size of the hydrophilic area A2. In this regard, the hydrophilic area A2 may be formed in a portion of the surface of the core particle 110, for example, an area in a range of 50% to 80% of the surface thereof. Alternatively, as shown in FIG. 3C, the area size of the exposed hydrophobic area A1 may be very small, and the second coating portion 130 may be provided on a significant portion of the surface of the core particle 110. In this regard, the hydrophilic area A2 may be formed in a portion of the surface of the core particle 110, for example, an area in a range of 80% inclusive to 100% exclusive of the surface thereof. Regardless of whether a ratio of the area sizes of the hydrophobic area A1 and the hydrophilic area A2 corresponds to FIG. 3A or FIG. 3B, at least a portion of the hydrophobic area A1 is exposed to the outside.

In some embodiments of the present disclosure, an additional film may be formed on the hydrophobic area A1 or the hydrophilic area A2.

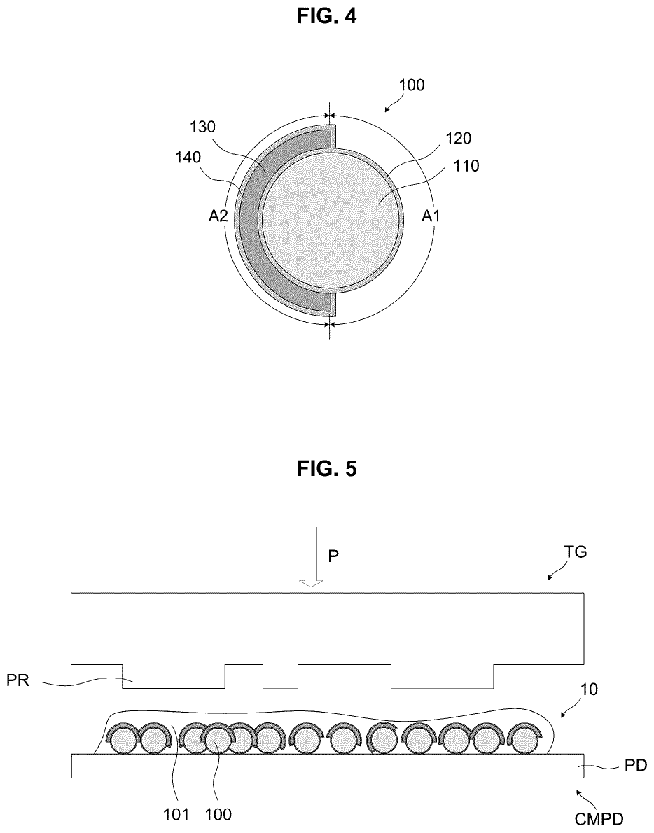

FIG. 4 is a cross-sectional view showing an abrasive particle according to some embodiments of the present disclosure, showing that a film portion 140 is formed on the hydrophilic area A2.

Referring to FIG. 4, the film portion 140 may be formed on the hydrophilic area A2 as an additional film to enhance chemical/physical properties different from those of the exposed first coating portion 120. The film portion 140 may be formed only on the second coating portion 130 of the hydrophilic area A2.

The film portion 140 may include a material that has chemical/physical properties opposite to those of the first coating portion 120. For example, when the first coating portion 120 is hydrophobic, the film portion 140 may include a material with high hydrophilicity.

In some embodiments of the present disclosure, the film portion 140 may include a specific charge. For example, the film portion 140 may include a cationic polymer or an anionic polymer. When the target to be polished is made of a polymer having a specific charge, the film portion 140 may be made of a polymer having a charge opposite to that of the target to be polished. The polymer with the opposite charge has an opposite charge to that of the target to be polished, and thus may be easily adsorbed to the surface of the target to be polished during the polishing process. For example, when the target to be polished is anionic, the film portion 140 may include a cationic polymer with an opposite charge thereto. When the film portion 140 is made of a polymer having opposite charges to that of the target to be polished, a percentage at which the Janus abrasive particles 100 are adsorbed to the target to be polished is improved, which may improve polishing efficiency.

The slurry composition for chemical mechanical polishing is applied to a chemical mechanical polishing apparatus and used to polish the target to be polished. That is, the slurry composition may be transferred onto a surface of the abrasive pad of the chemical mechanical polishing apparatus, the surface of the target to be polished may be placed such that the slurry composition is between the target and the pad, and then the surface of the target may contact the slurry composition. Thus, the surface may be polished with the slurry composition.

In some embodiments of the present disclosure, the formation of the film portion 140 may be optional and may be omitted.

The slurry composition for chemical mechanical polishing according to some embodiments of the present disclosure may use the Janus abrasive particles 100 as abrasive particles, thereby enabling efficient polishing of the target to be polished. Unlike the abrasive particles of existing technology, the Janus abrasive particles in the slurry composition according to some embodiments of the present disclosure may be on the abrasive pad of the polishing apparatus in the anisotropically oriented manner into a specific direction, thereby enabling efficient polishing of the target to be polished.

In the existing technology, the slurry composition for chemical mechanical polishing often includes silica (SiO₂) or ceria (CeO₂) as abrasive particles. The slurry composition containing silica or ceria particles has a low price, a simple manufacturing method, and high oxide/nitride selectivity. However, during a hydrophobization process for adsorption thereof to the abrasive pad of the chemical mechanical polishing apparatus, the agglomeration thereof occurs within the slurry composition before adsorption to the abrasive pad. When the polishing is carried out while the abrasive particles have agglomerated within the slurry composition, scratches may occur on the target to be polished, which may cause defects.

In some embodiments of the present disclosure, a partial area (hydrophobic area A1) of the surface of the abrasive particle is hydrophobic, so that the particle may be easily adsorbed to a hydrophobic abrasive pad of the chemical mechanical polishing apparatus. In particular, the abrasive particles in the slurry composition may be oriented in a predetermined direction due to the characteristics of the Janus abrasive particles 100 when being adsorbed on the abrasive pad. For example, when the abrasive pad of the chemical mechanical polishing apparatus is made of a hydrophobic material such as polyurethane, the first coating portions of the Janus abrasive particles may be adsorbed on the surface of the abrasive pad such that the Janus abrasive particles are oriented into the specific direction. In addition to polyurethane, the abrasive pad of the chemical mechanical polishing apparatus may be made of a hydrophobic material such as acrylic, epoxy, polyethylene, polystyrene, polyvinyl chloride, polytetrafluoroethylene, polydimethylsiloxane, and polyester. When the abrasive pad is made of the hydrophobic material other than polyurethane, the effect in which the abrasive particles are oriented in a predetermined direction may be obtained as described above.

In addition, the abrasive particles are easily absorbed onto the hydrophobic abrasive pad of the chemical mechanical polishing apparatus, while due to both the hydrophilic and hydrophobic properties, agglomeration between the abrasive particles is reduced or minimized.

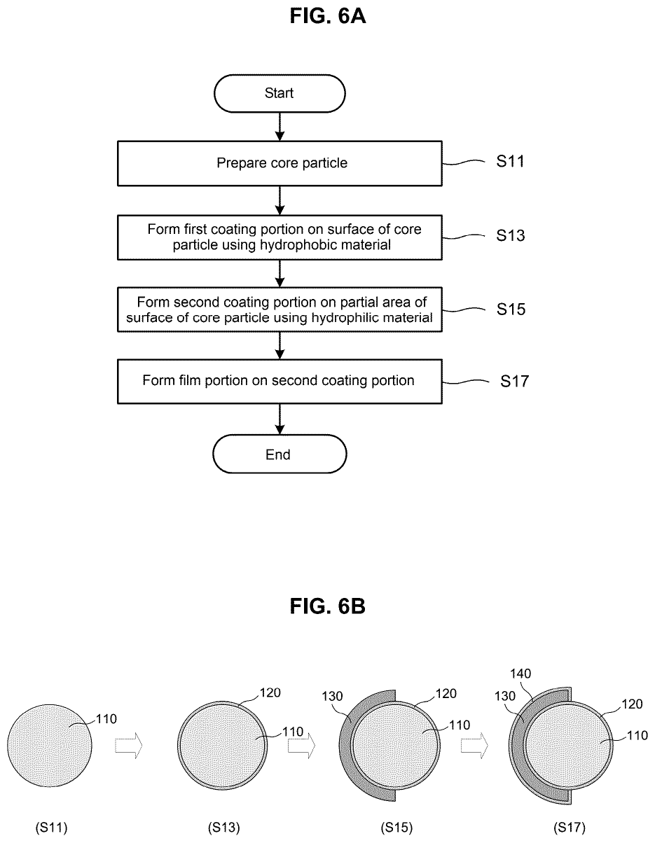

FIG. 5 is a conceptual diagram showing the anisotropic orientation of the Janus abrasive particles in a slurry composition for chemical mechanical polishing according to some embodiments of the present disclosure.

Referring to FIG. 5, the slurry composition for chemical mechanical polishing is placed on an abrasive pad PD of the chemical mechanical polishing apparatus.

Although not shown, the chemical mechanical polishing apparatus may include a head (not shown) on which a target TG to be polished is mounted and the abrasive pad PD that rotates in the same direction as a rotation direction of the head. A slurry composition 10 is provided between the target TG to be polished and the abrasive pad PD. Although not shown, the chemical mechanical polishing apparatus may further include a nozzle for providing the slurry composition 10 into between the target TG to be polished and the abrasive pad PD. The target TG to be polished is mounted on the head by surface tension or vacuum. With the slurry composition 10 interposed between the target TG to be polished and the abrasive pad PD, the head performs rotational and vibration movements, and the abrasive pad PD performs rotational movement to polish the target TG. In this regard, the head may pressurize the target TG to be polished with a pressure (P) toward the abrasive pad PD. Due to the head's own load and the applied pressure, the surface of the target TG to be polished and the abrasive pad PD come into contact with each other, and the slurry composition 10 flows along the contact surface. Accordingly, a mechanical removal action on the surface of the target TG to be polished is performed by the Janus abrasive particles 100 in the slurry composition 10, and a chemical removal action thereon is performed by the chemical components in the slurry composition 10. When there are irregularities on the target TG to be polished, a protruding portion PR first contacts the Janus abrasive particles 100. Because the pressure is concentrated on this protruding portion PR, the surface removal rate on the protruding portion PR is relatively higher than that in other portions. As the processing progresses, the protruding portion is removed uniformly over an area thereof.

The abrasive pad PD of the chemical mechanical polishing apparatus is positioned and oriented so that an upper surface thereof faces the target TG to be polished while the slurry composition 10 is interposed therebetween. The Janus abrasive particles 100 in the slurry composition 10 are placed on the abrasive pad PD. In this regard, the Janus abrasive particle 100 has a hydrophobic portion and a hydrophilic portion, and accordingly, the orientation thereof varies depending on whether the abrasive pad PD is hydrophobic or hydrophilic.

When the abrasive pad PD is hydrophobic, as shown, the hydrophobic portion of the Janus abrasive particles 100, that is, the hydrophobic area A1 receives an attractive force from the abrasive pad PD, and thus the abrasive pad PD may directly contact the hydrophobic area A1. The hydrophilic portion of the Janus abrasive particles 100, that is, the hydrophilic area A2 receive a repulsive force from the hydrophobic surface and thus is located far away from the surface of the abrasive pad PD. As a result, as shown in FIG. 5, the Janus abrasive particles 100 are oriented so that the hydrophobic area A1 is in contact with the abrasive pad PD and the hydrophilic area A2 faces the target TG.

According to some embodiments of the present disclosure, the Janus abrasive particles 100 perform rotational movement while polishing is in progress. When the Janus abrasive particles 100 rotate, it is difficult to maintain the orientations of the particles in the same direction, but the Janus abrasive particles 100 may exhibit a meaningful orientation due to their large area size. In particular, the Janus abrasive particles 100 may have the attraction force between the coating portions having the same physical properties (for example, the attraction force between the first coating portions 120 of different particles or the attraction force between the second coating portions 130 of different particles), the Janus abrasive particles 100 may have a specific directionality at a significant level. As a result, an orientation in a specific direction is possible compared to the case where existing particles other than the Janus abrasive particles 100 are randomly oriented.

When the partial area (e.g., hydrophilic area A2) of the Janus abrasive particles 100 faces the target TG to be polished, the polishing efficiency on the target TG to be polished may be improved. For example, when the second coating portion 130 is formed in the hydrophilic area A2 using ceria having the polishing selectivity relative to silicon oxide and silicon nitride, the second coating portion 130 may face the target TG, such that the polishing etch percentage may be significantly increased.

According to some embodiments of the present disclosure, as described above, the materials of the first coating portion 120 and the second coating portion 130 are different from each other, and the hydrophobic and hydrophilic areas of the first coating portion 120 and the second coating portion 130 vary. Thus, the Janus abrasive particles 100 may be on the abrasive pad PD in the oriented manner. The polishing is performed in that state, such that the polishing efficiency on a specific target TG may be improved.

Some embodiments of the present disclosure may include a method for manufacturing the Janus abrasive particles as described above.

The Janus abrasive particles according to some embodiments of the present disclosure may be manufactured by forming the first coating portion in the hydrophobic area and forming the second coating portion in the hydrophilic area. In this regard, the step of forming the first coating portion on the hydrophobic area of the core particle may be performed either before forming the second coating portion or after forming the second coating portion.

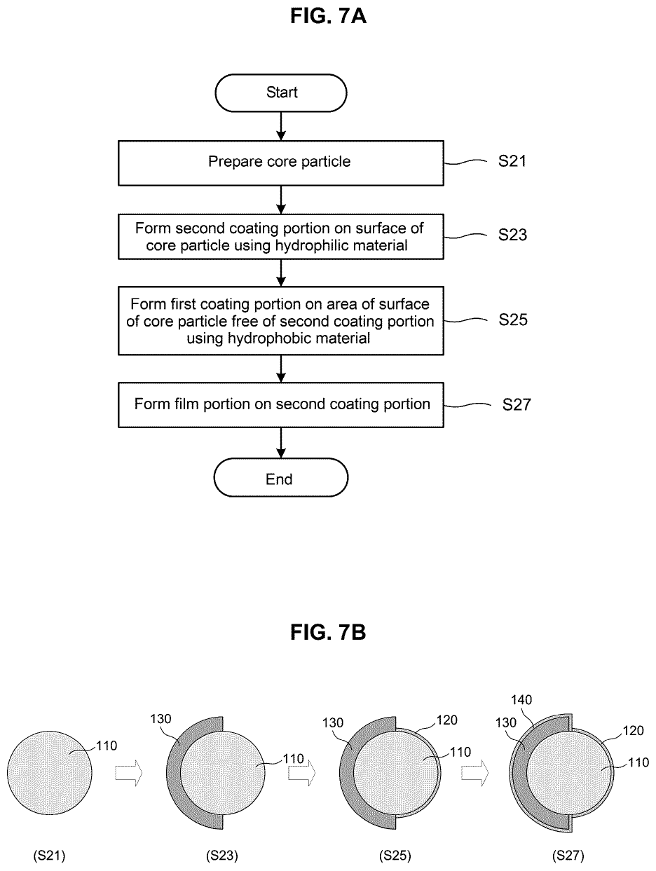

FIG. 6A is a flowchart sequentially showing a method for manufacturing Janus abrasive particles according to some embodiments of the present disclosure, and FIG. 6B is a cross-sectional view which sequentially shows a method for forming Janus abrasive particles according to some embodiments of the present disclosure.

Referring to FIG. 6A and FIG. 6B, in order to manufacture the Janus abrasive particles 100 according to some embodiments of the present disclosure, the core particles 110 are first prepared in S11. The core particle 110 may be provided in a single integrated body as described above, or may be provided in a core 111-shell 113 structure.

Next, the first coating portion 120 may be formed on the core particle 110 using a hydrophobic material in S13. The first coating portion 120 may be on and cover the surface of the core particle 110. The first coating portion 120 may be formed in various ways, for example, through coating.

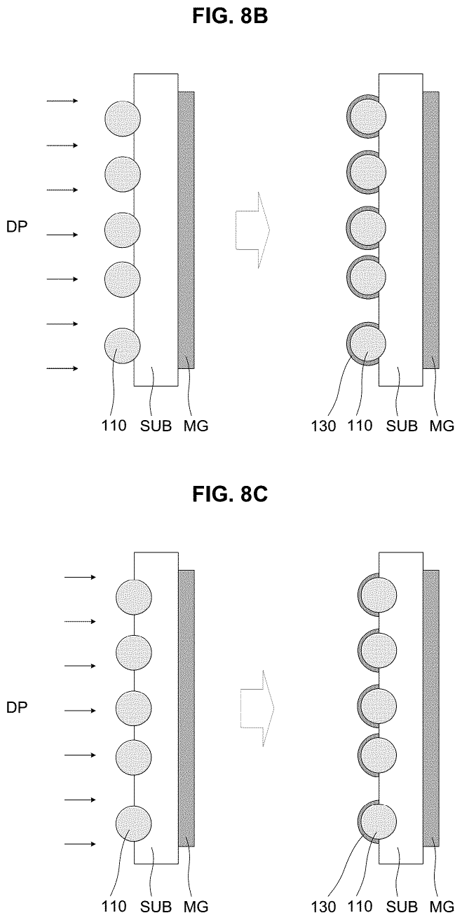

Thereafter, the second coating portion 130 may be formed on the core particle 110 on which the first coating portion 120 has been formed using a hydrophilic material in S15. The second coating portion 130 may be on or cover only a portion of the surface of the core particle 110, such that a portion of the first coating portion 120 formed on the surface of the core particle 110 on which the second coating portion 130 is not formed is exposed to the outside. Accordingly, the portion of the surface of the core particle 110 where the second coating portion 130 is formed is hydrophilic, and the portion of the surface thereof where the first coating portion 120 is exposed to the outside is hydrophobic. The second coating portion 130 may be formed on the core particles 110 via chemical vapor deposition, physical vapor deposition, coating, and/or solution phase reaction while the core particles 110 are in contact with a substrate SUB. The second coating portion 130 may be formed by the method shown in FIGS. 8A to 8C, which is described herein.

Next, the film portion 140 may be optionally formed in S17. The film portion 140 is intended to facilitate the orientation of the Janus abrasive particles 100 in a specific direction when the particles 100 are placed on the abrasive pad PD of the chemical mechanical polishing apparatus, and, for this reason, has the charges of opposite polarity to the polarity of the charges of the first coating portion 120. The film portion 140 may be formed only on the second coating portion 130.

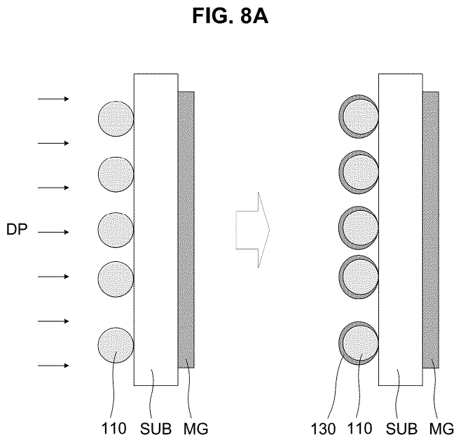

FIG. 7A is a flowchart sequentially showing a method for manufacturing another type of the Janus abrasive particles according to some embodiments of the present disclosure, and FIG. 7B a cross-sectional view which sequentially shows a method for forming the Janus abrasive particles according to some embodiments of the present disclosure.

Referring to FIG. 7A and FIG. 7B, in order to manufacture the Janus abrasive particles 100 according to some embodiments of the present disclosure, the core particles 110 are first prepared in S21. The core particle 110 may be provided in a single integrated body as described above, or may be provided in a core 111-shell 113 structure.

Next, the second coating portion 130 may first be formed on the core particle 110 using a hydrophilic material in S23. The second coating portion 130 may be on or cover only a portion of a surface of the core particle 110 rather than a surface thereof. The second coating portion 130 may be formed on the core particle 110 via chemical vapor deposition, physical vapor deposition, coating, and/or solution phase reaction while the core particle 110 is in contact with the substrate SUB. The second coating portion 130 may be formed by the method shown in FIGS. 8A to 8C, which is described herein.

Thereafter, the first coating portion 120 made of a hydrophobic material may be formed on a portion of the surface of the core particle 110 other than the portion of the surface of the core particles 110 on which the second coating portion 130 has been formed in S25. The first coating portion 120 may be on or cover an area of the surface of the core particle 110 that does not overlap with the second coating portion 130. Accordingly, the portion of the surface of the core particle 110 where the second coating portion 130 is formed is hydrophilic, and the portion of the surface thereof where the first coating portion 120 is formed is hydrophobic.

Next, the film portion 140 may be optionally formed in S27. The film portion 140 may be formed only on the second coating portion 130.

In some embodiments of the present disclosure, the second coating portion 130 may be formed on the core particle 110 via chemical vapor deposition or physical vapor deposition, or solution phase reaction while the core particle 110 is in contact with the substrate SUB. In this regard, the core particle 110 may be placed on the substrate SUB so that at least a portion of the core particle 110 is in contact with the substrate SUB. While the core particle 110 is in contact with the substrate SUB, the second coating portion 130 may be formed on the partial area of the surface of the core particle 110. According to some embodiments of the present disclosure, when forming the second coating portion 130 while the core particles 110 are in contact with the substrate SUB, a formation area size of the second coating portion 130 may be controlled based on a contact area size between the core particle 110 and the substrate SUB.

FIGS. 8A to 8C show examples of forming the second coating portion by varying the size of the contact area between the core particle and the substrate, respectively.

Referring to FIG. 8A to FIG. 8C, the contact area size of the core particles 110 with the substrate SUB may increase in an order of FIG. 8A, FIG. 8B, and FIG. 8C.

First, the core particles 110 are placed on the substrate SUB. The magnetic force may be used to place the core particles 110 on the substrate SUB. In particular, the core particles 110 may include a material having magnetism as described above. Thus, when a magnet MG is placed on an opposite surface to one surface of the substrate SUB on which the core particles 110 are placed, the core particles 110 may be attached to the surface of the substrate SUB due to the magnetic force of the magnet MG. The magnet MG may be an electromagnet or a permanent magnet.

In this regard, the contact area size of each core particle 110 with the substrate may vary depending on the softness of the substrate SUB and/or the strength of magnetic force. When the substrate SUB is soft, the core particles 110 may move toward the magnet MG due to the magnetic force acting on the core particles 110, and as a result, a recess may be formed in the surface of the substrate SUB by the moving core particle 110, and at the same time, the size of the contact area of the substrate with the surface of the core particle 110 may increase. When the substrate SUB is hard, the contact area size of the particle with the surface of the substrate SUB may be small even when the magnetic force is strong. In addition, when the magnetic force of the magnet MG is strong, the contact area size between the core particles 110 and the surface of the substrate SUB may increase even when the softness is weak. The hard substrate may be provided in various forms, such as a hard glass substrate, a metal substrate, and a silicon substrate. The soft substrate may be a polymer substrate made of soft gel or the like.

Referring to FIG. 8A, the substrate SUB is hard or the magnetic force is weak. When the core particle 110 contact the substrate SUB, the contact area size is not large. Referring to FIG. 8B, in a case where the substrate SUB has an appropriate degree of the softness and/or the magnetic force, the contact area size of the core particle 110 with the surface of the substrate SUB becomes larger than that in FIG. 8A. Referring to FIG. 8C, even when the substrate SUB has significant softness or when the magnetic force is very strong though the softness of the substrate SUB is low, the contact area size of the core particle 110 with the surface of the substrate SUB is very large.

In this way, while the core particles 110 are placed on the substrate SUB, the second coating portion 130 may be formed via chemical vapor deposition, physical vapor deposition, coating, and/or solution phase reaction in a direction DP perpendicular to the surface of the substrate SUB. As a result, the Janus abrasive particles as shown in FIG. 3C, FIG. 3B, and FIG. 3A may be formed using the core particles 110 formed by the methods of FIG. 8A to FIG. 8C, respectively.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A slurry composition used for chemical mechanical polishing, the slurry composition comprising:
a plurality of Janus abrasive particles; and
a solvent in which the plurality of Janus abrasive particles are dispersed,
wherein each of the plurality of Janus abrasive particles includes:
a core particle;
a first coating portion on a surface of the core particle; and
a second coating portion on the surface of the core particle,
wherein the each of the plurality of Janus abrasive particles has a hydrophobic area and a hydrophilic area defined by the first and second coating portions.

2. The slurry composition for the chemical mechanical polishing of claim 1, wherein the core particle is selected from the group consisting of silica, zirconia, titania, ceria, and surface-modified inorganic oxide particles, and combinations thereof.

3. The slurry composition for the chemical mechanical polishing of claim 2, wherein the core particle is made of silica, and the second coating portion is made of ceria.

4. The slurry composition for the chemical mechanical polishing of claim 1, wherein the core particle includes a core and a shell on the core.

5. The slurry composition for the chemical mechanical polishing of claim 4, wherein the core includes a metal oxide and the shell includes an inorganic oxide.

6. The slurry composition for the chemical mechanical polishing of claim 1, wherein the first coating portion includes a hydrophobic polymer.

7. The slurry composition for the chemical mechanical polishing of claim 6, wherein the hydrophobic polymer includes at least one of acrylic, epoxy, polyethylene, polystyrene, polyvinyl chloride, polytetrafluoroethylene, polydimethylsiloxane, polyester, and polyurethane.

8. The slurry composition for the chemical mechanical polishing of claim 1, wherein at least a portion of the second coating portion is on the first coating portion.

9. The slurry composition for the chemical mechanical polishing of claim 1, wherein the first coating portion includes a surface-modified inorganic oxide.

10. The slurry composition for the chemical mechanical polishing of claim 9, wherein the surface-modified inorganic oxide comprises a composite including one of a cationic polymer, an anionic polymer, or a nonionic polymer.

11. The slurry composition for the chemical mechanical polishing of claim 1, further comprising a film portion on the second coating portion of each of the plurality of Janus abrasive particles.

12. The slurry composition for the chemical mechanical polishing of claim 11, wherein the film portion includes an ionic polymer having charges of an opposite polarity to a polarity of a target to be polished.

13. The slurry composition for the chemical mechanical polishing of claim 1, wherein the second coating portion is on 50% inclusive to 100% exclusive of the surface of the core particle.

14. A particle for chemical mechanical polishing having a hydrophobicity and a hydrophilicity on respective surface areas thereon, the particle for chemical mechanical polishing comprising:
a core particle;
a first coating portion on a surface of the core particle; and
a second coating portion on the surface of the core particle,
wherein a hydrophobic area and a hydrophilic area are defined by the first and second coating portions.

15. A method for manufacturing Janus abrasive particles contained in a slurry composition for chemical mechanical polishing, the method comprising:
forming a hydrophobic first coating portion on at least a partial area of a surface of a core particle;
placing the core particle on a substrate so that at least a portion of the core particle contacts the substrate; and
forming a hydrophilic second coating portion on the core particle while the core particle is in contact with the substrate.

16. The method of claim 15, wherein the hydrophobic first coating portion is formed by coating a hydrophobic material on the surface of the core particle before placing the core particle on the substrate.

17. The method of claim 15, wherein the hydrophobic first coating portion is formed using chemical vapor deposition, physical vapor deposition, or solution phase reaction.

18. The method of claim 15, wherein the core particle is magnetic, and an electrode or a magnet is placed on an opposite surface to one surface of the substrate on which the core particle is positioned such that the substrate is between the electrode or the magnet and the core particle, and thus the core particle is attached to the substrate under a magnetic force.

19. The method of claim 18, wherein the substrate has softness, and a formation area size of the hydrophilic second coating portion is controlled based on a contact area size between the core particle and the substrate.

20. A chemical mechanical polishing method comprising:
transferring the slurry composition according to claim 1 onto a surface of an abrasive pad of a chemical mechanical polishing apparatus;
placing a surface of a polishing target such that the slurry composition is between the polishing target and the abrasive pad; and
contacting the surface of the polishing target with the slurry composition to polish the surface of the polishing target with the slurry composition.
